(19) United States
(12) Patent Application Publication
(10) Pub. No.: US 2011/0226739 A1
(43) Pub. Date: Sep. 22, 2011

(54) PROCESS CHAMBER LINER WITH APERTURES FOR PARTICLE CONTAINMENT

(75) Inventors: Ernest E. Allen, Rockport, MA (US); Appu Naveen George Thomas, Beverly, MA (US)

(73) Assignee: VARIAN SEMICONDUCTOR EQUIPMENT ASSOCIATES, INC., Gloucester, MA (US)

(21) Appl. No.: 12/727,547

(22) Filed: Mar. 19, 2010

(51) Int. Cl. C23F 1/08; C23C 16/00

(52) U.S. Cl. 216/67; 118/723 R

(57) ABSTRACT

An apparatus for use within a process chamber is provided. The apparatus includes a liner adapted to cover the sidewalls of the process chamber, with apertures corresponding to various inlets and outlets in the process chamber. In addition, the liner has one or more apertures on its bottom surface, which allow particles to pass through the liner. The liner is designed to be shorter in height than the sidewalls of the process chamber. This allows the liner to be placed within the chamber such that its bottom surface is above the floor of the process chamber. This minimizes the possibility of particles that have fallen onto the process chamber floor becoming re-suspended at a later time. According to a second aspect of the disclosure, a bottom liner is provided. This liner can be used in conjunction with a conventional liner or in a process chamber without a liner.

### BACKGROUND

A plasma processing apparatus generates a plasma in a process chamber for treating a workpiece supported by a platen in the process chamber. A plasma processing apparatus may include, but not be limited to, doping systems, etching systems, and deposition systems. The plasma is generally a quasi-neutral collection of ions (usually having a positive charge) and electrons (having a negative charge). The plasma has an electric field of about 0 volts per centimeter in the bulk of the plasma. In some plasma processing apparatus, ions from the plasma are attracted towards a workpiece. In a plasma doping apparatus, ions may be attracted with sufficient energy to be implanted into the physical structure of the workpiece, e.g., a semiconductor substrate in one instance.

Turning to FIG. 1, a block diagram of one exemplary plasma doping apparatus 100 is illustrated. The plasma doping apparatus 100 includes a process chamber 102 defining an enclosed volume 103. A gas source 104 provides a primary dopant gas to the enclosed volume 103 of the process chamber 102 through the mass flow controller 106. A gas baffle 170 may be positioned in the process chamber 102 to deflect the flow of gas from the gas source 104. A pressure gauge 108 measures the pressure inside the process chamber 102. A vacuum pump 112 evacuates exhausts from the process chamber 102 through an exhaust port 110. An exhaust valve 114 controls the exhaust conductance through the exhaust port 110.

The plasma doping apparatus 100 may further includes a gas pressure controller 116 that is electrically connected to the mass flow controller 106, the pressure gauge 108, and the exhaust valve 114. The gas pressure controller 116 may be configured to maintain a desired pressure in the process chamber 102 by controlling either the exhaust conductance with the exhaust valve 114 or a process gas flow rate with the mass flow controller 106 in a feedback loop that is responsive to the pressure gauge 108.

The process chamber 102 may have a chamber top 118 that includes a first section 120 formed of a dielectric material that extends in a generally horizontal direction. The chamber top 118 also includes a second section 122 formed of a dielectric material that extends a height from the first section 120 in a generally vertical direction. The chamber top 118 further includes a lid 124 formed of an electrically and thermally conductive material that extends across the second section 122 in a horizontal direction.

The plasma doping apparatus further includes a source 101 configured to generate a plasma 140 within the process chamber 102. The source 101 may include a RF source 150 such as a power supply to supply RF power to either one or both of the planar antenna 126 and the helical antenna 146 to generate the plasma 140. The RF source 150 may be coupled to the antennas 126, 146 by an impedance matching network 152 that matches the output impedance of the RF source 150 to the impedance of the RF antennas 126, 146 in order to maximize the power transferred from the RF source 350 to the RF antennas 126, 146.

The plasma doping apparatus may also include a bias power supply 190 electrically coupled to the platen 134. The plasma doping system may further include a controller 156 and a user interface system 158. The controller 156 can be or include a general-purpose computer or network of general-purpose computers that may be programmed to perform desired input/output functions. The controller 156 may also include communication devices, data storage devices, and software. The user interface system 158 may include devices such as touch screens, keyboards, user pointing devices, displays, printers, etc. to allow a user to input commands and/or data and/or to monitor the plasma doping apparatus via the controller 156. A shield ring 194 may be disposed around the platen 134 to improve the uniformity of implanted ion distribution near the edge of the workpiece 138. One or more Faraday sensors such as Faraday cup 199 may also be positioned in the shield ring 194 to sense ion beam current.

In operation, the gas source 104 supplies a primary dopant gas containing a desired dopant for implantation into the workpiece 138. The source 101 is configured to generate the plasma 140 within the process chamber 102. The source 101 may be controlled by the controller 156. To generate the plasma 140, the RF source 150 resonates RF currents in at least one of the RF antennas 126, 146 to produce an oscillating magnetic field. The oscillating magnetic field induces RF currents into the process chamber 102. The RF currents in the process chamber 102 excite and ionize the primary dopant gas to generate the plasma 140.

The bias power supply 190 provides a pulsed platen signal having a pulse ON and OFF periods to bias the platen 134 and hence the workpiece 138 to accelerate ions 109 from the plasma 140 towards the workpiece 138. The ions 109 may be positively charged ions and hence the pulse ON periods of the pulsed platen signal may be negative voltage pulses with respect to the process chamber 102 to attract the positively charged ions. The frequency of the pulsed platen signal and/or the duty cycle of the pulses may be selected to provide a desired dose rate. The amplitude of the pulsed platen signal may be selected to provide a desired energy.

Particles may be generated on the sidewalls of the process chamber 102 during plasma processing. These particles may be of any composition and may include, but are not limited to, silicon, carbon, silicon oxide and aluminum oxide. These particles also may be caused by sputtering of the workpiece or the tool itself. In some embodiments, a liner 193 may be introduced which protects the sidewalls of the process chamber 102. This liner 193 typically extends the height of the process chamber 102 sidewalls, reaching first section 120, and along the floor or the process chamber 102. However, particles may still accumulate on the side surfaces 197 of the liner 193. Over time, these particles may be subject to external forces that may be greater than the adhesive strength holding them to the side surface 197 of the liner 193. These external forces may include, but are not limited to, electrostatic forces, shock waves from sudden changes in pressure, and gravitational forces due to continued deposition on the sidewalls or liner 193.

When the adhesive strength of these particles is overcome, they free themselves from the sidewalls (or liner 193) and may become suspended in the plasma (if active), or fall due to the gravitational force. In some cases, these particles fall atop the workpiece 138, thereby affecting the functionality of at least a portion of the workpiece 138 and possibly resulting in lower device yields. In other cases, these particles may fall to the floor of the process chamber 102. However, even in this case, the electrostatic forces caused by the plasma may attract the particles upward from the floor of the process chamber 102. This force causes the particles to become suspended again in the volume within the chamber and increases the possibility that the particles will ultimately land atop the workpiece 138, thereby affecting the processing of the workpiece 138 and the device yield.

One way to minimize the yield decreases of the workpieces 138 is to clean the sidewalls and floor of the process chamber 102 more regularly. Another method requires regular cleaning or replacement of the liner 193. However, these steps result in additional downtime for the plasma doping apparatus 100, which lowers the effective yield of the apparatus.

Therefore, there exists a need for an apparatus that will reduce the possibility of particles landing atop the workpiece and the possibility of particles lowering the device yield.

### SUMMARY

According to a first aspect of the disclosure, an apparatus for use within a process chamber is provided. The apparatus includes a liner adapted to cover the sidewalls of the process chamber, with apertures corresponding to various inlets and outlets in the process chamber. In addition, the liner has one or more apertures on its bottom surface, which allow particles to pass through the liner. The liner is designed to be shorter in height than the sidewalls of the process chamber. This allows the liner to be placed within the chamber such that its bottom surface is above the floor of the process chamber. This minimizes the possibility of particles that have fallen onto the process chamber floor becoming re-suspended at a later time. In some embodiments, the apertures in the bottom surface have a width that is less than the thickness of the bottom surface.

According to a second aspect of the disclosure, a bottom liner is provided. This liner has one or more apertures and can be used in conjunction with a conventional liner and in a process chamber without a liner. The bottom liner is held above the bottom of the process chamber, such as by one or more spacers.

### BRIEF DESCRIPTION OF THE DRAWINGS

For a better understanding of the present disclosure, reference is made to the accompanying drawings, in which like elements are referenced with like numerals, and in which:

FIG. 1 is a block diagram of a plasma doping apparatus of the prior art;

FIG. 2 is a block diagram of a plasma doping apparatus consistent with the disclosure;

FIG. 3 is a first embodiment of a liner consistent with the disclosure;

FIG. 4 is a second embodiment of a liner consistent with the disclosure;

FIG. 5 is a bottom view of the embodiment of FIG. 3;

FIG. 6 shows a spacer used with an embodiment; and

FIG. 7 is an embodiment of a bottom liner used in conjunction with a conventional liner.

### DETAILED DESCRIPTION

As described above, traditional plasma processing apparatus may generate particles that adhere to the sidewalls of the process chamber 102. As described above, a liner 193 may be used to eliminate adhesion to sidewalls of the process chamber 102, however adhesion to the liner 193 may still present yield issues due to particle buildup and subsequent separation.

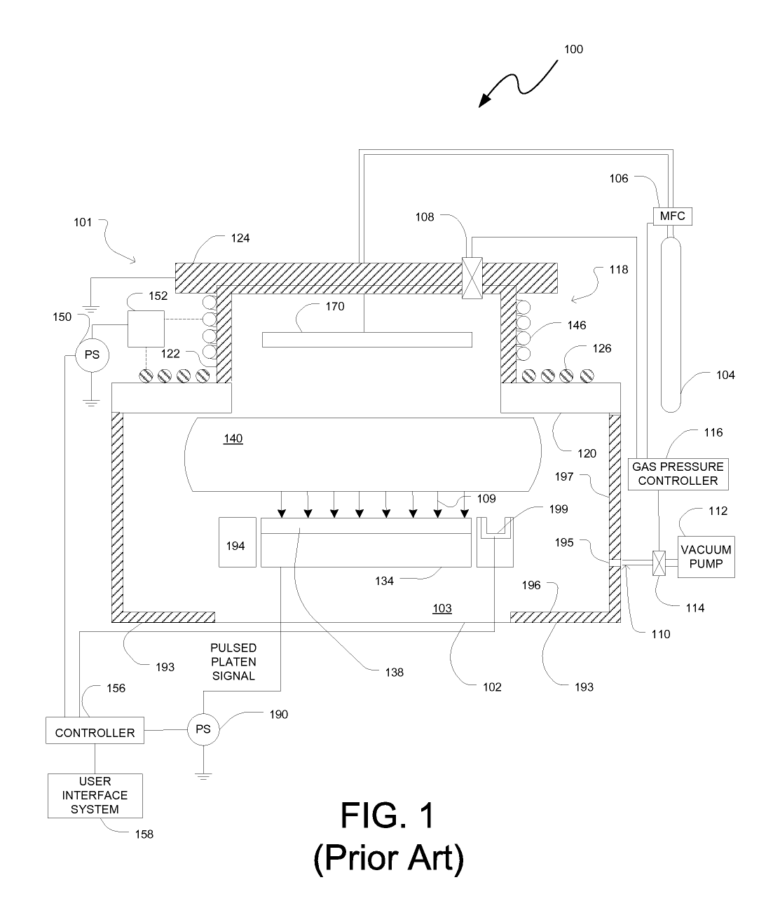

Currently, as shown in FIG. 1, the liner 193 extends the entire height of the chamber sidewall, reaching from the first section 120 to the floor of the chamber, and along the floor of the process chamber 102. In some embodiments, the chamber is cylindrical in shape, thereby resulting in a liner 193 with a bottom surface 196 that is annular, with side surfaces 197 extending upward from the outer circumference of the annular bottom surface 196. The side surfaces 197 are preferably orthogonal to the bottom surface 196. In some embodiments, the process chamber 102 may have one or more inlets and/or outlets along the sidewalls of the chamber. For example, the exhaust port 110 may be located along the sidewall of process chamber 102. In the case of inlets or outlets located along the sidewalls of the process chamber, the liner 193 contains a corresponding aperture 195 in the side surface 197, thereby allowing the free flow of gasses into and out of the process chamber 102.

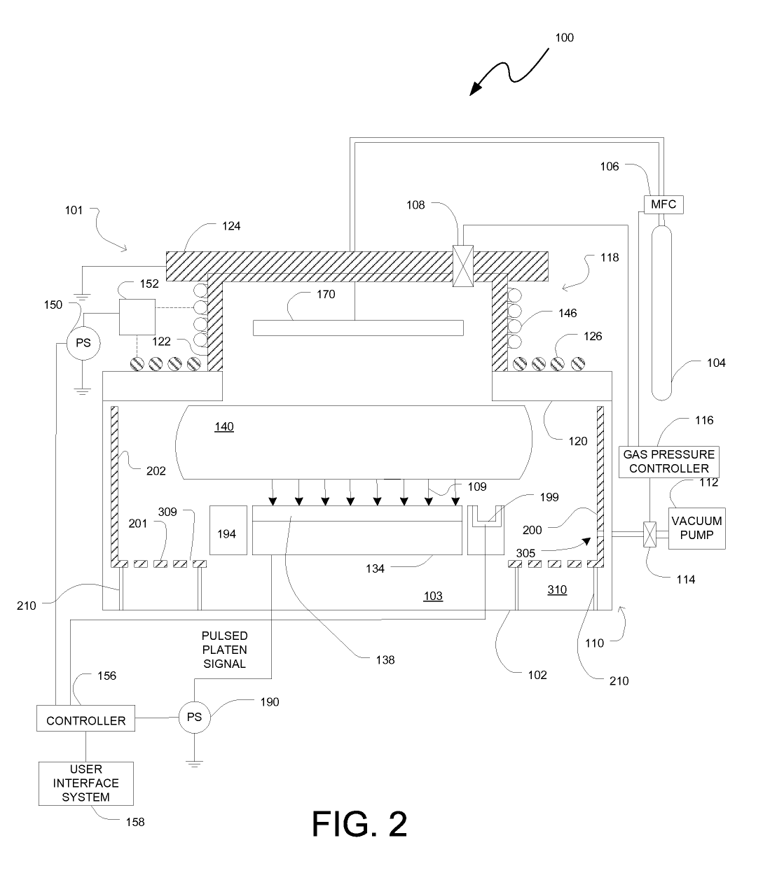

According to one embodiment of the present disclosure, a liner is defined as shown in FIG. 2. The liner 200 may be constructed of aluminum or another electrically conductive material and may be of unitary construction. In some embodiments, the liner 200 is coated, such as with a thermal sprayed silicon. As described above, the liner 200 includes a bottom surface 201, which is annular in shape. Extending upward from the outer circumference of the bottom surface 201 is a side surface 202. The side surface 202 of the liner 200 has a height that is less than that of the sidewalls of the process chamber 102. To insure that the liner 200 protects the sidewalls of the process chamber 102, spacers 210 are introduced beneath the liner 200. These spacers 210 elevate the liner 200 so that the upper edge of the side surface 202 of the liner 200 covers the top portion of the sidewall of the process chamber 102. In other words, the height of the side surface 202 added to the height of the spacer 210 is preferably about the same as the height of the sidewalls in the process chamber 102. Thus, the liner 200 extends to first section 120. This allows the liner 200 to protect the sidewalls of the process chamber 102.

The spacers 210 are preferably constructed of an electrically conductive material. The spacers 210 may be aluminum bushings, or another structure, and there may be one or more spacers 210 used to support the liner 200. The height of the spacer may be between 0.25″ and 1.00″ inches tall. In some embodiments, it is preferable that the bottom surface 201 of the liner 200 is no higher than the platen 134.

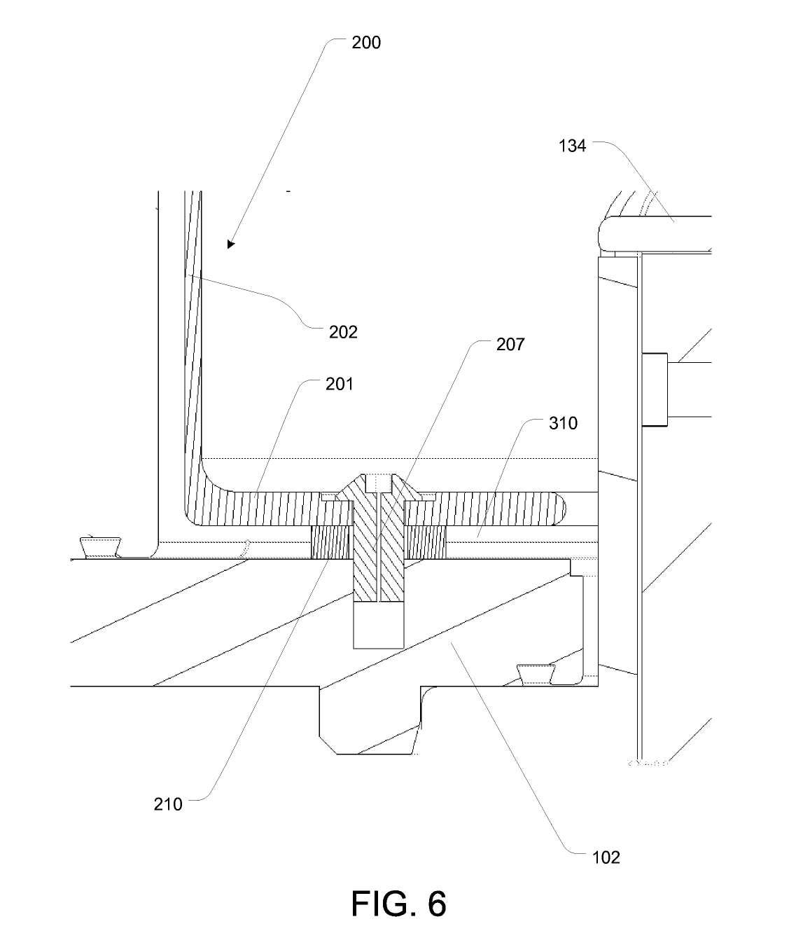

FIG. 6 shows an expanded view of one embodiment of the liner 200 and the spacer 210. In this embodiment, the liner 200 is installed so as to be offset from the bottom of the process chamber 102 through the use of spacer 210. A fastener 207 is used to secure the bottom surface 201 of the liner 200 and the spacer 210 to the process chamber 102. The fastener 207 is preferably electrically conductive and may be a screw or bolt. The spacer creates a volume 310 between the floor of the process chamber 102 and the bottom surface 201 of the liner.

Referring to FIGS. 2-4, it can be seen that the liner 200 may have one or more apertures 305 along its side surface 202. As described above, these apertures preferably align with inlet or outlets in the sidewalls of the process chamber 102. Additional apertures may be needed to allow the workpiece 138 and platen 134 to be moved into and out of the process chamber 102. The side surface 202 of the liner 200 may be between 0.1 and 0.25 inches in thickness.

As described above, the bottom surface 201 of the liner 200 is preferably annular in shape, where the inner diameter may be greater than or equal to the diameter of the platen 134, so that the liner 200 fits around the platen 134 in the process chamber 102. In some embodiments, the inner diameter is between 15.5″ and 16.0″ inches. The outer diameter of the annular bottom surface 201 may be made to be roughly the same as the diameter of the process chamber 102, so that the side surfaces 202 of the liner 200 are in close proximity to the sidewalls of the process chamber 102 during normal operation, such as less than 0.125″ away. The outer diameter may be between 21.5″ and 22.0″ inches.

In addition to being elevated from the floor of the process chamber 102, the liner 200 also has apertures 309 on its bottom surface 201. These apertures 309 allow particles to fall through the bottom surface 201 and become trapped in the volume 310 defined between the floor of the process chamber 102 and the bottom surface 202 of the liner 200. In some embodiments, the spacers 210 are affixed to the bottom surface 201 of the liner 200, such as by fasteners 207 that pass through one or more fastener holes 307. In one embodiment, the fasteners 207 are screws.

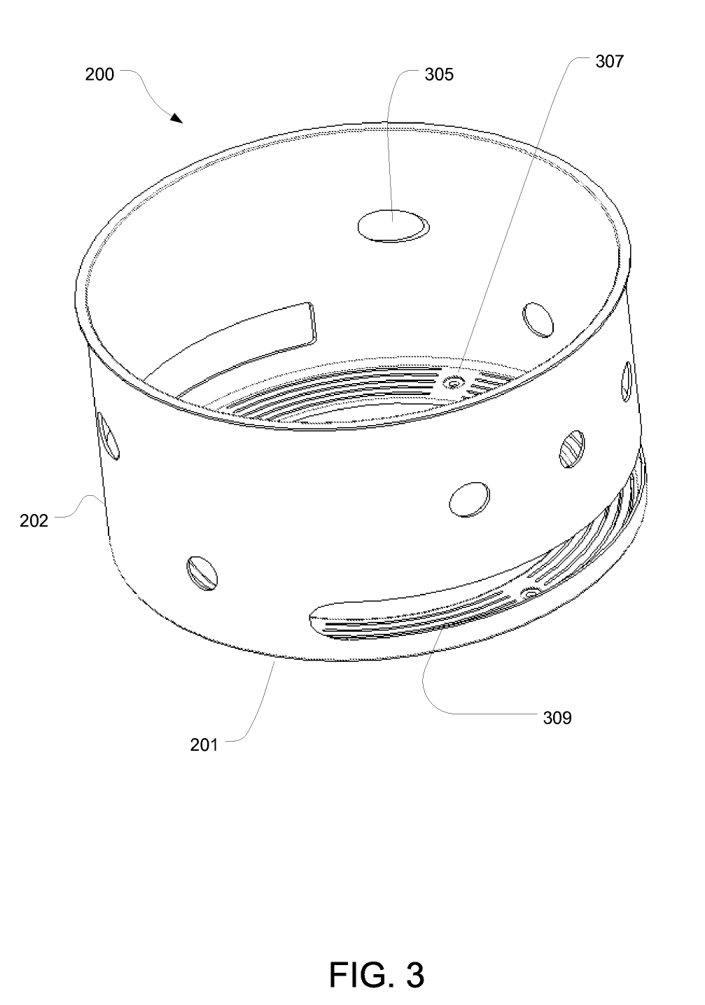

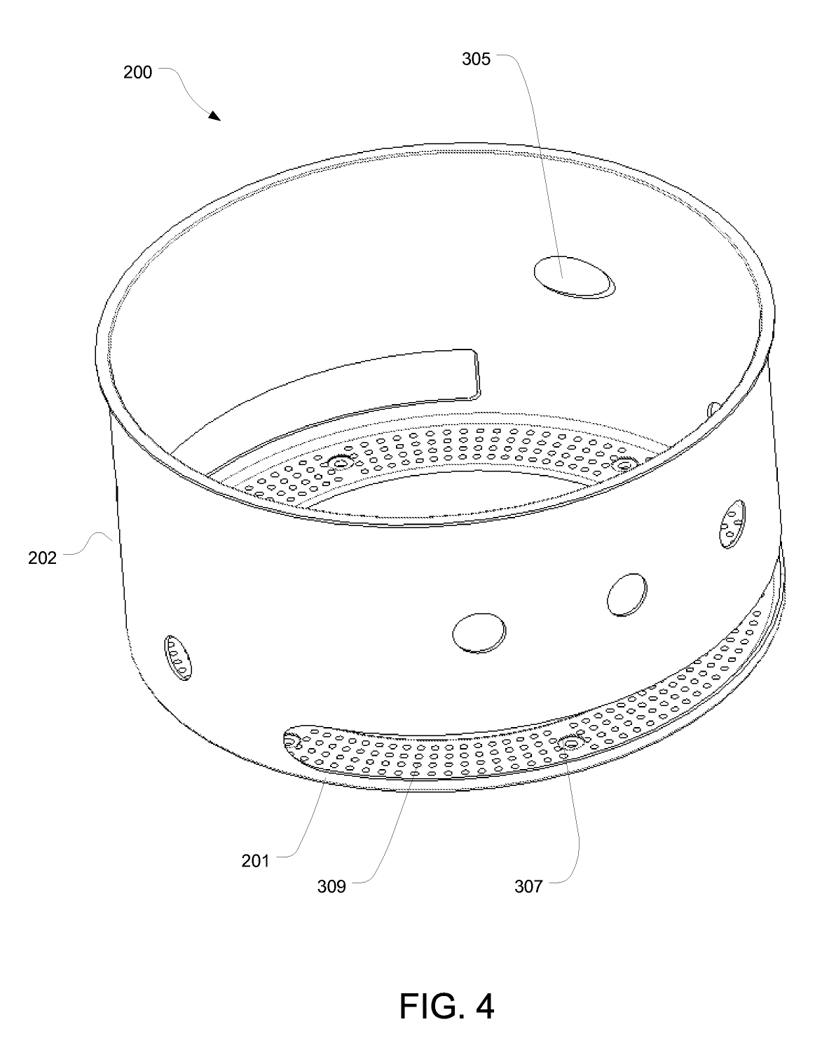

The apertures 309 can be configured in a variety of ways. For example, FIG. 3 shows the apertures as concentric curved, arcuate slots. FIG. 4 shows the apertures are radial rows of holes. In addition, any other pattern of holes, or any shape of hole may be used to form the apertures 309.

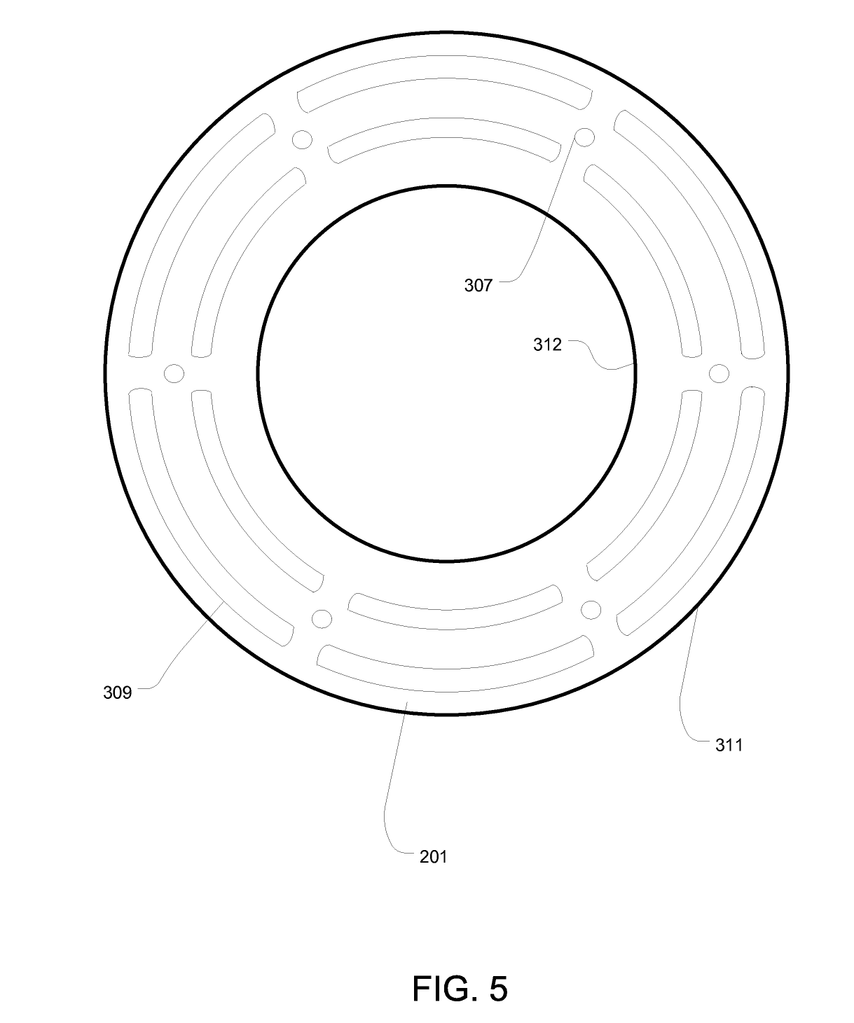

FIG. 5 shows a bottom view of one embodiment of the bottom surface 201 of the liner 200. In this embodiment, six fastener holes 307 are provided to allow attachment to a corresponding number of spacers 210. In this embodiment, the apertures 309 are concentric curved arcuate slots, having a width of about 0.125 inches. The apertures 309 may be positioned as close to one another as desired, as long as sufficient structural support is maintained. In some embodiments, over 40% of the area between the outer diameter 311 and the inner diameter 312 is open. In other words, at least 40% of the material that would exist between the outer diameter 311 and inner diameter 312 is removed by the presence of the apertures 309. In other embodiments, the percentage of open area on the bottom surface 201 is higher than 50%. The amount of open space maximizes the possibility that a particle will fall through the bottom surface 201 and get trapped in the volume 310 between the bottom surface 201 of the liner 200 and the floor of the process chamber 102. Although only two sets of concentric slots are shown, the disclosure is not limited to this embodiment; any suitable number of apertures may be used.

Once particles falls into the volume 310 between the bottom surface 201 of the liner 200 and the floor of the process chamber 102, it is beneficial that these particles remain trapped within this volume. The constant changes in pressure in the process chamber 102 may cause the particles to be agitated and float upward from the floor of the process chamber 102. In some embodiments, the apertures are designed to minimize the possibility of particles floating upward through the apertures. In some embodiments, this is achieved by controlling the ratio of the thickness of the bottom surface 201 of the liner 200 to the width of the aperture 309, also referred to as the aspect ratio of the aperture. For example, in some embodiments, the width of the apertures 309 is about 0.125 inches, while the thickness of the bottom surface of the liner is 0.25 inches. In this case, the ratio of surface thickness to aperture width is 2. In other embodiments, ratios of greater than 1 are suitable. In a two dimensional aperture 309, the characteristic dimension is typically the smaller dimension. For example, the characteristic dimension of the aperture 309 may be defined as its diameter (in the case of circular apertures 309) or its width (in the case of slotted apertures 309).

By creating an aspect ratio greater than 1, the possibility of a particle floating upward and passing through the aperture is reduced. This reduces the number of particles that fall atop the workpiece 138, and consequently improve the device yield of the apparatus.

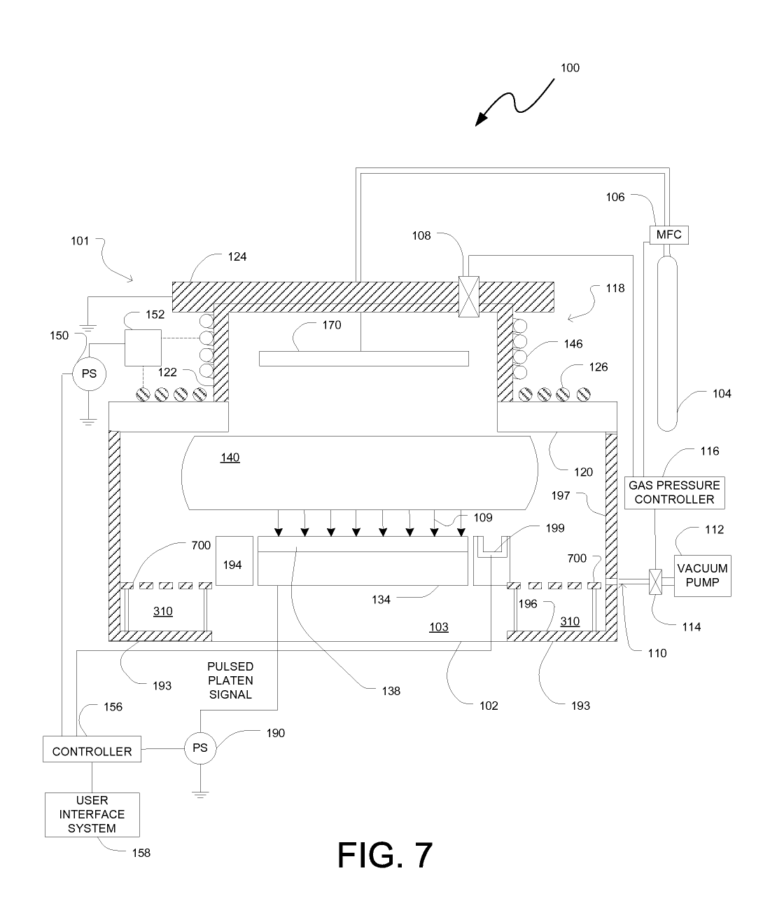

In another embodiment, the liner comprises only a bottom surface. FIG. 7 shows an embodiment where a liner 700, having only a bottom surface, is used in a process chamber 102. In this embodiment, a convention liner 193 is installed to line the sidewalls of the process chamber 102 to facilitate cleaning. Liner 700 is installed on top of liner 193, and may be secured to liner 193, or process chamber 102 using fasteners. The liner 700 is offset from the bottom surface 196 of liner 193, such as by spacers 210. As described above, the spacers may be electrically conductive and may be aluminum bushings or any other suitable means. In some embodiments, the spacers are between 0.25″ and 1.0″ in height. In some embodiments, the fasteners secure the liner 700 to the pre-existing liner 193. In other embodiments, the fasteners secure the liner 700 directly to the process chamber 102, such as by passing through a hole in the pre-existing liner 193.

In other embodiments, liner 700 can be used without a pre-existing liner 193. In this embodiment, the liner 700 is fastened to the floor of the process chamber 102 using fasteners through spacers 210.

In the embodiments employing liner 700, a volume 310 is still created between the floor of the process chamber 102 and the bottom surface of the liner 700. In addition, the bottom surface of liner 700 comprises a plurality of apertures, as described above with respect to liner 200. Thus, particles pass through the apertures in liner 700 and become trapped in the volume 310. In some embodiments, the apertures comprise over 40% of the area of the liner 700. In some embodiments, the aspect ratio of the apertures is greater than 1.

Furthermore, the liner 700 has dimensions similar to the bottom surface of liner 200. In other words, it is annular in shape with an inner diameter of between about 15.5″ and 16.0″ and an outer diameter of between about 21.5″ and 22.0″. The apertures of liner 700 may be of any pattern, such as those shown in FIGS. 3-5.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A device for reducing particles within a plasma processing apparatus, said apparatus having sidewalls and a floor, and wherein a platen is positioned on said floor comprising:
a liner comprising:
a side surface, wherein the height of said side surface is less than the height of said sidewall and is configured to contact said sidewall; and
a bottom surface, spaced above said floor, and defining one or more apertures through which particles may pass such that said particles fall into a volume defined between said floor and said bottom surface; and
one or more spacers affixed to said bottom surface and configured to space said bottom surface above said floor.

2. The device of claim 1, wherein said bottom surface has a thickness and said apertures have a width, and an aspect ratio of said thickness to said width is greater than 1.

3. The device of claim 1, wherein said platen is positioned at a height above said floor and said spacers are used to position said bottom surface at a height which is less than the height of said platen.

4. The device of claim 1, wherein said apertures comprise a plurality of circular holes.

5. The device of claim 1, wherein said apertures comprise a plurality of concentric curved arcuate slots.

6. The device of claim 5, wherein said bottom surface is about 0.25 inches thick and each of said plurality of concentric curved arcuate slots is about 0.125 inches in width.

7. The device of claim 1, wherein said bottom surface is annular in shape, wherein the inner diameter is sized to allow said bottom surface to be placed around said platen and said outer diameter is about the same dimension as the diameter of said plasma processing apparatus.

8. The device of claim 7, wherein said apertures occupy at least 40% of said bottom surface.

9. A plasma processing apparatus, comprising:
a floor;
a top section;
a cylindrical sidewall, extending from said floor to said top section, said floor, top section and sidewall defining a cylindrical chamber;
a platen located in said cylindrical chamber, at a height greater than said floor and less than said top section;
a liner comprising:
an annular shaped bottom surface defining one of more apertures; and one or more spacers positioned to support said bottom surface at a height above said floor and below said platen, so as to define a volume between said floor and said bottom surface.

10. The processing apparatus of claim 9, wherein said annular ring comprises an inner diameter sized to allow said bottom surface to be placed around said platen and said outer diameter is about the same dimension as the diameter of said plasma processing apparatus.

11. The processing apparatus of claim 9, wherein fasteners secure said liner to said floor.

12. The processing apparatus of claim 9, wherein said apertures comprise a plurality of circular holes.

13. The processing apparatus of claim 9, wherein said apertures comprise a plurality of concentric curved arcuate slots.

14. The processing apparatus of claim 13, wherein said bottom surface is about 0.25 inches thick and each of said plurality of concentric curved arcuate slots is about 0.125 inches in width.

15. The processing apparatus of claim 9, wherein said apertures occupy at least 40% of said bottom surface.

16. The processing apparatus of claim 9, further comprising a second liner, said second liner comprising side surfaces configured to line said sidewall and a bottom surface configured to line said floor, and whereby said liner is positioned atop said second liner.

17. A plasma processing apparatus, comprising:
a floor;
a top section;
a cylindrical sidewall, extending from said floor to said top section, said floor, top section and cylindrical sidewall defining a cylindrical chamber;
a platen located in said chamber, at a height greater than said floor and less than said top section;
a liner comprising:
a cylindrical side surface, shorter in length than said sidewall, and positioned to cover said sidewall from said top section to a position above said floor;
an annular shaped bottom surface connected on its outer diameter to said side surface and having an inner diameter large enough to pass over said platen, said bottom surface defining one of more apertures; and
one or more spacers positioned to support said bottom surface at a height above said floor and below said platen, so as to define a volume between said floor and said bottom surface.

18. The apparatus of claim 17, wherein said bottom surface has a thickness and said apertures have a width and the ratio of said thickness to said width is greater than 1.

19. The apparatus of claim 17, wherein said apertures comprise concentric curved arcuate slots.

20. The apparatus of claim 17, wherein said apertures occupy at least 40% of the area of said annular shaped bottom surface.
